(19) United States
(12) Patent Application Publication
(10) Pub. No.: US 2024/0038870 A1
(43) Pub. Date: Feb. 1, 2024

(54) SOLUTION-PHASE PROCESSED VERTICAL SCHOTTKY DIODE AND METHOD OF MAKING A VERTICAL SCHOTTKY DIODE

(71) Applicant: The Board of Trustees of the University of Illinois, Urbana, IL (US)

(72) Inventors: Kyekyoon KIM, Champaign, IL (US); Hyungsoo CHOI, Champaign, IL (US); Riley VESTO, Urbana, IL (US)

(21) Appl. No.: 18/227,575

(22) Filed: Jul. 28, 2023

Related U.S. Application Data
(60) Provisional application No. 63/394,042, filed on Aug. 1, 2022.

(51) Int. Cl. H01L 29/66; H01L 29/872

(52) U.S. Cl. CPC H01L 29/66143; H01L 29/872

(57) ABSTRACT

A solution-phase processed vertical Schottky diode comprises a stack of films on a substrate, where the stack of films includes: a first electrode film comprising a noble metal; a first semiconducting film on the first electrode film, where the first semiconducting film comprises zinc oxide doped with an electron donor metal at a first dopant concentration; a second semiconducting film on the first semiconducting film, where the second semiconducting film comprises zinc oxide doped with the electron donor metal at a second dopant concentration higher than the first dopant concentration; and a second electrode film on the second semiconducting film, where the second electrode film comprises a noble metal.

### RELATED APPLICATION

The present patent document claims the benefit of priority under 35 U.S.C. 119(e) to U.S. Provisional Patent Application No. 63/394,042, which was filed on Aug. 1, 2022, and is hereby incorporated by reference in its entirety.

### TECHNICAL FIELD

The present disclosure relates generally to Schottky diodes and more particularly to a solution-phase processed Schottky diode.

### BACKGROUND

Internet of Things applications require massive distribution of low-profile sensors with the ability to wirelessly communicate and potentially transmit power. This is especially the case in industry and agricultural applications where the device needs are enormous. As such, rectifying and radio frequency (RF)-power conversion circuitry would benefit from cost-effective processing methods with high throughput.

Metal oxides are promising semiconducting materials for low-cost rectifying circuitry. They tend to be n-type with large bandgaps and electron mobilities and may be doped to directly control their conductivities. The most common metal oxide platform is the In—Ga—Zn—O family of alloys, due to their mobilities. However, the inclusion of In and Ga can significantly increase the materials cost. Therefore, efforts have been made to produce diodes using ZnO alone at a small cost in performance.

Recently, high-performance ZnO RF Schottky diodes have been produced using a coplanar nanogap design. These diodes are impressive but require multiple steps alternating between metallization and solution processing to achieve the nanogap, lengthening the processing time and limiting the throughput. In addition, the reliance on vacuum processing for metallization limits the choice and size of substrates. Vacuum metallization is pervasive in the production of metal oxide Schottky diodes due to the reliance on distinct metals for asymmetric contacts.

### BRIEF SUMMARY

A solution-phase processed vertical Schottky diode comprises a stack of films on a substrate, where the stack of films includes: a first electrode film comprising a noble metal; a first semiconducting film on the first electrode film, where the first semiconducting film comprises zinc oxide doped with an electron donor metal at a first dopant concentration; a second semiconducting film on the first semiconducting film, where the second semiconducting film comprises zinc oxide doped with the electron donor metal at a second dopant concentration higher than the first dopant concentration; and a second electrode film on the second semiconducting film, where the second electrode film comprises a noble metal. The noble metal of the second electrode film may be the same as or different from the noble metal of the first electrode film.

A solution-phase method of producing a vertical Schottky diode includes: generating a spray of charged droplets, each charged droplet comprising a metal precursor; collecting the charged droplets on a heated substrate, the metal precursor decomposing and/or reacting to form a film comprising a metal species; repeating the generating and the collecting successively with selected metal precursors to form a stack of the films on the substrate; and selecting the metal precursors such that the stack comprises: a first electrode film; a first semiconducting film on the first electrode film; a second semiconducting film on the first semiconducting film; and a second electrode film on the second semiconducting film, thereby forming a vertical Schottky diode.

### BRIEF DESCRIPTION OF THE DRAWINGS

FIG. 1 is a flow chart showing steps in a solution-phase method to produce a vertical Schottky diode.

FIG. 2 shows a schematic of an apparatus for carrying out flow-limited field-injection electrostatic spraying (FFESS) to achieve all solution-phase processing of a vertical Schottky diode.

FIG. 3 shows a schematic of an exemplary vertical Schottky diode with +/− indicating the placement of the anode and cathode, respectively.

FIG. 4 shows /(2V)//(−2V) ratio of forward and reverse bias currents for the interface between Ag and Al:ZnO films measured by contacting both films with tungsten probes.

FIG. 5 shows a dark-field optical micrograph (30×) of an exemplary fabricated vertical Schottky diode under contact using tungsten probes (W) with the top-most layer in each region defined and the length of the cathode contact indicated.

FIG. 6 shows scanning electron microscope (SEM) images of a cross-section of a fabricated diode, all at the same magnification, with each successive image demonstrating a different region of the device where the respective films are defined.

FIG. 7 shows a current-vs-voltage curve of a fabricated diode, where the ratio of /(2V)//(−2V) is indicated.

FIG. 8 shows Cheung plots used for extraction of the diode parameters; linear regression fits yield Rₛ=3.95 kΩ, n=6.4, and ϕ_{b}=0.64 V.

### DETAILED DESCRIPTION

All solution-phase processing of a vertical Schottky diode is described in this disclosure. The solution-phase approach may entail flow-limited field-injection electrostatic spraying (FFESS) with a total process time of less than two hours at temperatures below 300° C. This methodology may allow for cost-effective processing of rectifying and RF power conversion circuitry, enabling mass production of vertical Schottky diodes and other devices for Internet of Things applications.

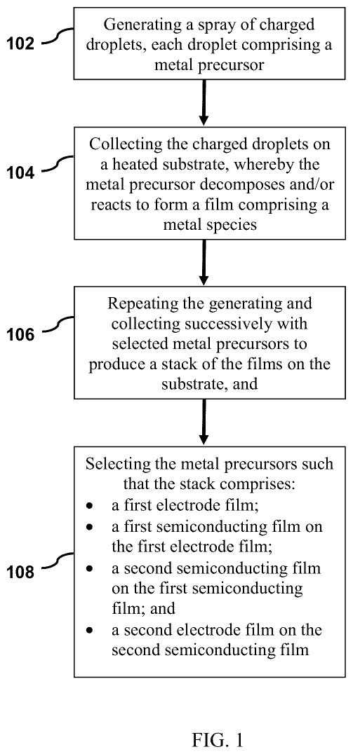

Referring to the flow chart of FIG. 1, the solution-phase method of producing a vertical Schottky diode includes generating 102 a spray of charged droplets, where each charged droplet comprises a metal precursor. The charged droplets are collected 104 on a heated substrate, e.g., a substrate having a temperature (T) greater than 30° C. and less than 300° C. The metal precursor decomposes and/or reacts to form a film comprising a metal species on the heated substrate. The generating and collecting steps are repeated 106 successively with selected metal precursors to produce a stack of the films on the heated substrate. The metal precursors are selected 108 such that the stack comprises: a first electrode film; a first semiconducting film on the first electrode film; a second semiconducting film on the first semiconducting film; and a second electrode film on the second semiconducting film. As will be discussed below, the first and second electrode films may comprise a noble metal (e.g., Ag), and the first and second semiconducting films may comprise doped zinc oxide (ZnO). A vertical Schottky diode is thus formed using solution-phase processing without the need for a vacuum environment or vapor-phase deposition. The vertical diode structure provides an advantage over coplanar nanogap devices in terms of current density, allowing for higher power applications. In addition, the vertical diode design allows for minimization of the length between contacts (the first and second electrode films) by controlling the thickness of the first and second semiconducting films without requiring nanoscale patterning or self-assembled monolayers.

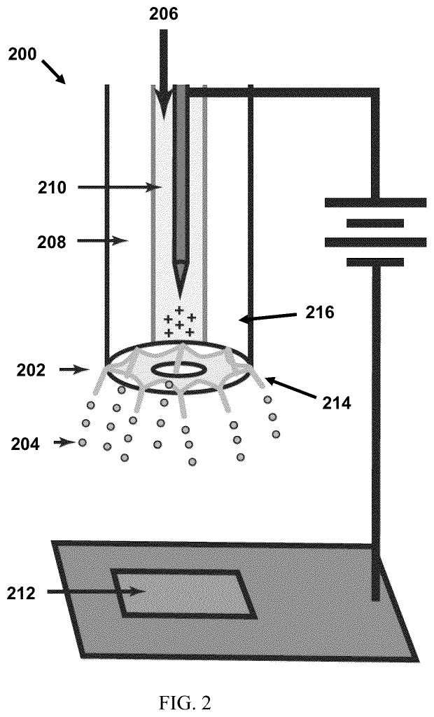

Referring now to the apparatus 200 shown schematically in FIG. 2, the spray 202 of charged droplets 204 may be generated by FFESS. That is, charge 216 may be field injected into a solution 206 comprising the metal precursor and a solvent in order to generate the spray 202. The field injection may take place by flowing the solution 206, which may be referred to as a precursor solution, through a nozzle 208 containing an inner electrode 210, and applying a charging voltage to the inner electrode 210. The charged droplets 204 comprising the metal precursor may be collected on a heated substrate 212 positioned in opposition to a downstream opening 214 of the nozzle 208. The generation of the spray 202 and the collection of the charged droplets 204 may be described collectively as solution-phase deposition. The charged droplets 204 are in the liquid phase, in contrast to other deposition methods that utilize vapor-phase precursors.

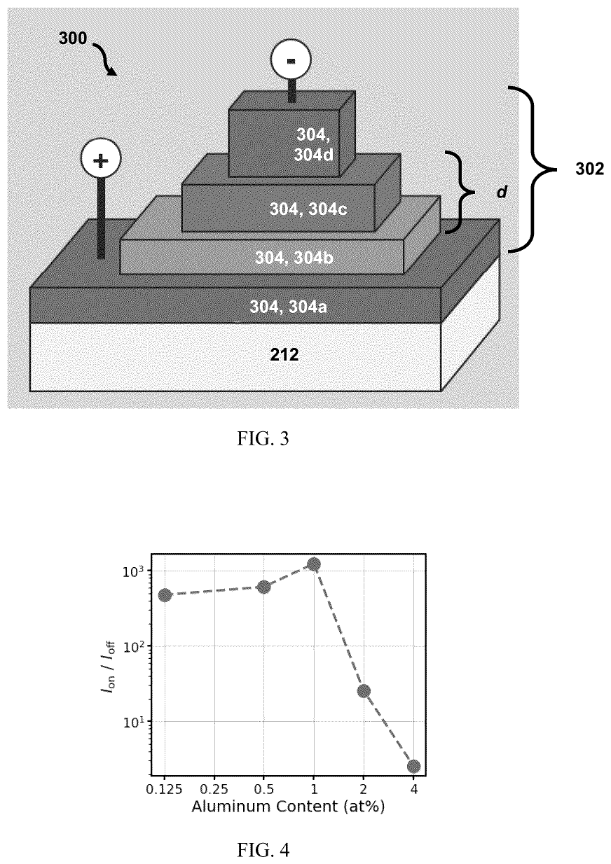

The charged droplets 204 may include, in addition to the metal precursor, the solvent mentioned above, typically an organic solvent in which the metal precursor is soluble. In some examples, the charged droplets 204 may comprise more than one metal precursor, e.g., to form the first and/or second semiconducting films. It is understood that the term “metal precursor” used throughout this disclosure may refer to a metalorganic compound or salt that includes a metal species. As described above, the metal precursor decomposes and/or reacts on the heated (30° C.<T<300° C.) substrate 212 to form a film comprising the metal species; any solvent present may evaporate. By repeating this solution-phase process with selected metal precursors, a stack of films, where each film in the stack has a desired composition, may be formed. In particular, a vertical Schottky diode 300, as illustrated in FIG. 3, may be fabricated by FFESS.

Before discussing the method in further detail, the composition and thin-film structure of the solution-phase processed vertical Schottky diode are described. Referring to FIG. 3, the vertical Schottky diode 300 comprises a stack 302 of films 304 on a substrate 212, where the stack 302 includes: (a) a first electrode film 304a comprising a noble metal, (b) a first semiconducting film 304b comprising zinc oxide doped with an electron donor metal at a first dopant concentration, (c) a second semiconducting film 304c comprising zinc oxide doped with the electron donor metal at a second dopant concentration higher than the first dopant concentration, and (d) a second electrode film 304d, also comprising a noble metal. As illustrated in the schematic of FIG. 3, the first electrode film 304a is formed on the substrate 212, the first semiconducting film 304b is formed on the first electrode film 304a, the second semiconducting film 304c is formed on the first semiconducting film 304b, and the second electrode film 304d is formed on the second semiconducting film 304c.

The noble metal of the first electrode film 304a may be different from the noble metal of the second electrode film 304d. Alternatively, the first and second electrode films 304a,304d may comprise the same noble metal (e.g., silver (Ag)), in contrast to prior art Schottky diodes, which have asymmetric metal contacts formed from different metals. In such an example, the solution-processed Schottky diode 300 may achieve asymmetric operation due to the presence of the two semiconducting (ZnO) films 304b,304c of different doping levels between the first and second electrode films 304a,304d, as described below. The noble metal(s) may comprise Ag, Au and/or Pt. Ag may be particularly suitable for solution-phase processing.

The electron donor metal for the ZnO semiconducting films 304b,304c may comprise Al, In, or Ga, but Al may be preferred due to its lower cost. The electron donor metal supplies an electron to the ZnO, such that the semiconductor films 304b,304c may be referred to as n-type or n-doped. As indicated above, the first and second semiconducting films 304b,304c may contain different amounts of the electron donor metal (or “dopant”). In one example, the first semiconducting film 304b comprises ZnO doped with Al at a first dopant concentration, and the second semiconducting film 304c comprises ZnO doped with Al at a second dopant concentration higher than the first dopant concentration. Preferably, the first dopant concentration is selected to form a Schottky contact with the first electrode film 304a, and the second dopant concentration is selected to form a tunneling contact with the second electrode film 304d. For example, the first dopant concentration may be less than 1 at. %, e.g., as low as 0.2 at. %, and the second dopant concentration may be higher than 1 at. %, e.g., as high as 4 at. %. It is contemplated that the first dopant concentration may be 0 at. %, in which case the first semiconducting film 304b may be described as undoped. Alternatively, the first dopant concentration may be greater than 0 at. %. For example, the first dopant concentration may be in a range from about 0.2 at. % to about 0.3 at. %, and the second dopant concentration may be in a range from about 2 at. % to about 4 at. % to achieve the desired performance.

The benefit of selecting the dopant concentration of the first and second semiconducting films 304b,304c as described above may be understood in reference to FIG. 4, which plots /(2V)//(−2V), labeled /on//off, versus aluminum content for an interface of a Ag electrode film and an Al-doped ZnO (Al:ZnO) semiconducting film. The forward and reverse bias currents are measured by contacting both films with tungsten probes. As indicated above, the doping of the first semiconducting (ZnO) film 304b may be chosen to maximize conductivity while forming a Schottky contact with the first electrode (Ag) film 304a, whereas the doping of the second semiconducting (ZnO) film 304c may be chosen to promote tunneling current through the Ag-to-ZnO barrier. Referring to FIG. 4, up to 1 at. % Al, the current ratio increases due to the higher Al:ZnO conductivity, allowing for higher forward current. Above 1 at. % Al, the reverse bias tunneling current increases, causing the ratio to approach unity at 4 at. % Al. The latter allows for the construction of the non-rectifying contact in this vertical Schottky diode design.

Referring again to the schematic of FIG. 3, in this exemplary vertical diode structure, an areal size of each of the films 304 in the stack 302 may decrease in a direction away from the substrate 212. Such a diode structure may be formed by employing a shadow mask (e.g., a polyimide mask) to define a reduced droplet collection area relative to the underlying film, e.g., with each successive deposition. As indicated above, the term “deposition” may be understood to refer collectively to the generation and collection of the charged droplets to form each film. It is also contemplated that the areal size of each of the films 304 may be the same throughout the stack 302. Alternatively, the areal size may be different for one or more of the films 304 and the same for others, where any differences may be achieved with shadow masking.

Also as shown in the exemplary vertical diode schematic of FIG. 3, the thickness of some or all of the films 304 in the stack 302 may increase in a direction away from the substrate 212. This increase in thickness 304 may be associated with the shadow mask used to control the areal size of the films 304 as described above, since the shadow mask may focus the spray of charged droplets. In other examples, the thickness of some or all of the films 304 in the stack 302 may be similar or the same, or may decrease in a direction away from the substrate 212. Typically, each film 304 in the stack 302 has a thickness of 1 micron or less, 500 nm or less, and/or 100 nm or less. In particular, each of the first and second semiconducting films 304b,304c may have a thickness of 800 nm or less, 400 nm or less, 200 nm or less, or 100 nm or less. Typically, the films 304 are at least 50 nm in thickness. In this vertical Schottky diode configuration, the combined thickness of the first and second semiconductor films 304b,304c defines a distance d as shown in FIG. 3 between the first and second electrode films 304a,304d, which is preferably as small as possible. For example, the distance d may be about 450 nm or less.

The films 304 in the stack 302 may be polycrystalline and/or nanocrystalline (e.g., having a crystallite or grain size of about 100 nm or less). Due to the control possible with FFESS, where the charged droplets 204 may be uniform in size and/or less than about 100 nm in width or diameter, the crystallites in each film 304 may also be highly uniform. For example, the crystallites of a given film 304 may exhibit a deviation of less than about 10% from an average or nominal crystallite size. The substrate 212 may be rigid or flexible. In one example, the substrate 212 comprises glass. In another example, the substrate 212 comprises a polymer.

Returning now to the description of the method: As indicated above in reference to FIG. 2, field injection to produce the charged droplets 204 may take place by flowing the solution 206 through a nozzle 208 containing an inner electrode 210, and applying a charging voltage to the inner electrode 210. The charging voltage may lie in a range from about 10 kV to about 40 kV, or from about 15 kV to about 25 kV, and a flow rate of the solution 206 through the nozzle 208 may lie in a range from about 5 μl/min to about 50 μl/min, or from about 10 μl/min to about 30 μl/min. The downstream opening 214 of the nozzle 208 may be positioned within about 6 cm of the substrate 212. The temperature of the substrate 212 may be, in some examples, 290° C. or less, or 200° C. or less. Lower temperatures may be advantageous for polymeric or other flexible substrates 212. Typically, the temperature is at least 100° C.

The charged droplets 202 comprise metal precursor(s) selected 106 to form each film 304 in the stack 302. Each metal precursor may comprise a metalorganic compound or salt that includes a metal species. Given the composition of the stack 302 of films 304, the selected metal precursors may include a first metal precursor and a fourth metal precursor comprising a noble metal (which may be the same or different as indicated above), and second metal precursors and third metal precursors comprising zinc and the electron donor metal, respectively.

More specifically, to form the first and second electrode films 304a,304d which may comprise the noble metal, such as silver, a metalorganic compound or salt comprising the noble metal (e.g., Ag) may be employed. For example, silver(I) 2-[2-(2 methoxyethoxy)ethoxy]acetate, silver 2-ethylhexnoate, silver pivalate, silver 2-(2 methoxyethoxy)acetate, and/or silver oxalate may be used as the first and fourth metal precursors.

To form each of the first and second semiconducting films 304b,304c, which may comprise zinc oxide doped with an electron donor metal such as Al, In, or Ga, a metalorganic compound or salt comprising zinc may be employed as the second metal precursor along with a metalorganic compound or salt comprising the electron donor metal (e.g., Al) as the third metal precursor. For example, the second metal precursor may comprise zinc acetate, zinc nitrate, a zinc carboxylate such as zinc propionate, zinc butanoate, zinc pentanoate, zinc 2-ethylhexanoate, zinc methoxyacetate, zinc methoxyethoxyacetate, and/or zinc methoxyethoxyethoxyate. The third metal precursor may comprise aluminum acetylacetonate, aluminum nitrate, aluminum isopropoxide, aluminum tri-sec-butoxide, aluminum alkyl 3-oxobutanoate, such as ethyl 3-oxobutanoate and butyl 3-oxobutanoate, aluminum tri-n-butoxide, and/or aluminum ethyl hexanoate. The dopant concentration of each of the semiconducting films 304b,304c may be controlled by the amount of the third metal precursor employed relative to the amount of the second metal precursor, that is, the relative amount of the third metal precursor. For example, a larger relative amount of the third metal precursor may be employed to form the second semiconducting film 304c compared to that used to form the first semiconducting film 304b, such that the second dopant concentration (of the second semiconducting film 304c) is higher than the first dopant concentration (of the first semiconducting film 304b).

As indicated above, the charged droplets 202 and the precursor solution 206 from which they are obtained may include, in addition to the metal precursor(s), a solvent, typically an organic solvent capable of dissolving the metal precursor(s). Suitable solvents may comprise, for example, ethanol, methanol, propanol, acetone, butanol, alkoxyethanol, such as methoxy ethanol, ethoxy ethanol, and methoxyethoxy ethanol, ethylene glycol, propylene glycol, dimethyl sulfoxide (DMSO), dimethylformamide (DMF), and/or acetonitrile. In some examples, the charged droplets 202 and the solution 206 may also include water and/or one or more other additives, such as an amine, e.g., triethylamine, which may promote sol-gel reactions during deposition.

A shadow mask may be positioned on or above the substrate to block a portion of the charged droplets, thereby controlling an areal size and shape of the film formed from the collected droplets, as described above. In other words, the shadow mask may be used to pattern the film. As illustrated in FIG. 3, an areal size of the film (e.g., the first semiconducting film 304b) may be reduced compared to the substrate 212 or an underlying film (e.g., the first electrode film 304a) when a shadow mask is employed. The shadow mask may be electrically insulating or electrically conductive. In the latter case, the method may further comprise applying a bias voltage to the shadow mask during deposition. The resolution of the pattern can be influenced by applying a bias voltage to the mask and/or by changing the distance between the mask and the substrate. Typically, the shadow mask is positioned about 200 μm or less from the substrate.

In contrast to vapor-phase film deposition methods (e.g., chemical vapor deposition (CVD), physical vapor deposition (PVD), and/or vacuum metallization), a vacuum environment or other controlled environment (e.g., inert gas) is not required for the solution-phase method described in this disclosure. Instead, the solution-phase process may be carried out in air at atmospheric pressure. In addition, the process is rapid. Generation and collection of the charged droplets to form each film 304 may be carried out in 15 min or less. Prior to deposition of the second electrode film 304d (the final film in the stack 302), the substrate may be held at the temperature T for a suitable time period (e.g., 45 min or less) to remove any incorporated hydrogen (which may have a Fermi-level pinning effect) from the semiconducting films 304b,304c. Formation of the stack 302 of films 304 to form the vertical Schottky diode 300 may take place in 120 minutes or less. Once the second electrode film 304 is formed, the solution-phase process may be halted and the stack 302 of films 304 may be actively or passively cooled.

As described above, FFESS employs field-injection to charge precursor solutions 206, forming a spray 202 which may be described as one or more jets and which comprises charged droplets 204 of controlled sizes. These charged droplets 204 can conformally coat heated substrates 212, producing high-purity thin films 304 of a desired composition from metal precursors. The additional energy from Coulombic repulsion may allow for production of highly oriented crystalline films at reduced temperatures. The ability to control droplet size allows FFESS to produce dense films of predetermined thicknesses. This capability is exploited in the example described below to stack films of Ag and Al-doped ZnO (Al:ZnO), so as to produce a vertical Schottky diode.

### EXAMPLE

Fabrication

In this example, the precursor solution consisted of 0.1 M zinc (II) acetate and aluminum (III) acetylacetonate in EtOH. Sol-gel reactions were carried out during deposition through the addition of triethylamine (TEA) and water (1:3:0.5 Zn:H₂O:TEA) to the precursor solution. Depositions were performed using a 17-kV charging voltage and 16-μl/min flowrate. For the metal contacts, highly conductive Ag was deposited directly from solution, enabling all solution-phase deposition. This was performed using a solution-phase precursor comprising 0.2 M silver (I) 2-[2-(2-methoxyethoxy)ethoxy]acetate in ethanol with a 30 μl/min flowrate and 20 kV charging voltage.

To achieve asymmetric operation of the diode, two Al:ZnO films were deposited, one with 0.25 at. % Al doping on the bottom and the other 4 at. % Al doping on the top. The doping of the bottom layer was chosen to maximize conductivity while forming a Schottky contact with the Ag, whereas the doping of the top layer was chosen to promote tunneling current through the Ag-to-ZnO barrier. FIG. 4, discussed above, demonstrates this behavior.

The exemplary, proof-of-concept diode was produced by successive depositions of 15 min Ag, 10 min 0.25 at. % Al:ZnO, 10 min 4 at. % Al:ZnO films, and 15 min Ag onto a glass coverslip substrate at 230° C., with decreasing deposition areas defined using a Kapton tape (polyimide) shadow mask. FIG. 3 provides a schematic of the final diode structure with the nesting layers (films) and the placement of the anode and cathode probes indicated.

Results

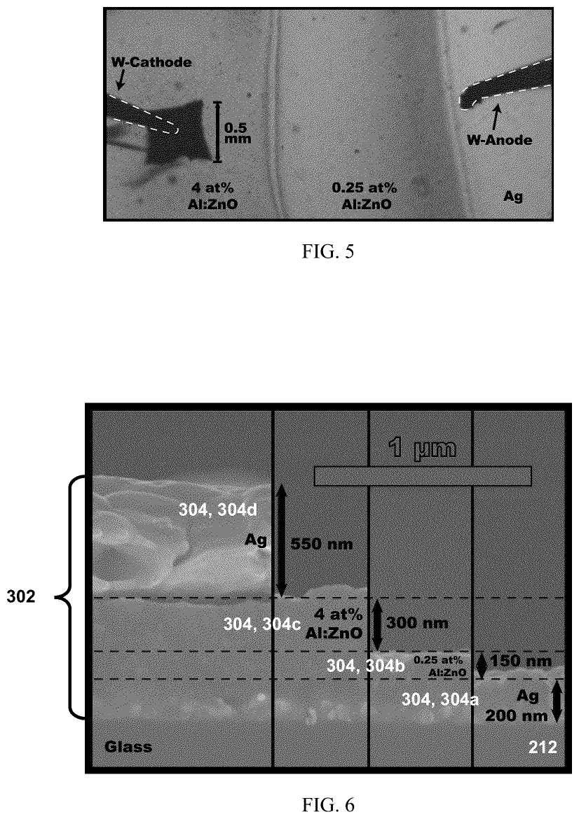

An optical micrograph of the Schottky diode under contact with tungsten probes is shown in FIG. 5, demonstrating that the final Ag layer which defines the working area of the device to be 0.5×0.5 mm². Despite the simplicity of the shadow-masking approach, well defined features are easily produced. Scanning electron microscopy (SEM) images of the diode cross-section are shown in FIG. 6, demonstrating the respective film thicknesses in the stack 302 of films 304. Each successive image demonstrates a different region of the cross-section where the respective films 304a,304b,304c,304d are defined. The film thickness increases per layer due to the Kapton mask, which focuses the charged droplets. This resulted in the topmost Ag film 304d to be 550 nm thick, protecting the diode from scratching during probing.

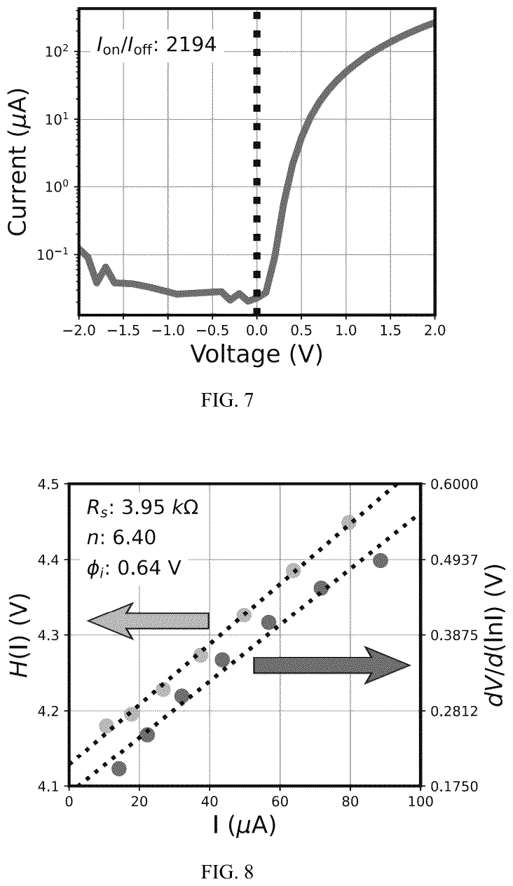

The current-vs-voltage curve of the diode is demonstrated in FIG. 7. The ratio of the forward and reverse bias current was I(2V)/I(−2V)=2194. This demonstration of rectification indicates the promise for the technology. Further improvement may be achieved by increasing the forward current. This may be achieved by increasing the doping of the first Al:ZnO film, increasing the cathode area, and/or decreasing the Al:ZnO thicknesses.

For further characterization of the diodes, the plotting methods of Cheung et al. were employed [11]. This was accomplished by noting, based on the Schottky diode equation:

$$\frac{dV}{d ( ln I )} = \frac{n {k}_{B} T}{q} + {IR}_{S} ,$$

where Rₛ is the series resistance of the diode, n is the ideality factor, q is the electron charge, and k_{B}T=25.7 meV is the room temperature thermal energy. The left-hand side was calculated using central differences and plotted on the right-axis in FIG. 8. By linear regression, we obtain Rₛ=3.95 kΩ and n=6.4. The series resistance is larger than desired which indicates the limiting factor of the forward current. The ideality is large, seemingly limited by recombination due to traps at the Ag-to-Al:ZnO interface.
The barrier height, ϕ_{b}, may be calculated by noting:

$$H ( I ) ≡ V - \frac{n {k}_{B} T}{q} ln \frac{I}{{A}^{*} {A}_{e f f} {T}^{2}} = n {ϕ}_{b} + {IR}_{s} ,$$

where A* is Richardson's constant, taken to be 8.6 A/cm²K², and A_{eff} is the effective area of the diode, assumed to be the area of the anode. This function is plotted on the right-axis of FIG. 8. By linear regression, Rₛ=3.99 kΩ and ϕ_{b}=0.64 V is obtained. The second fit to the Rₛ is within margin to the first fit. The barrier height is within margin to the difference in expected work functions of the silver and ZnO.

To summarize, a prototype Schottky diode was produced entirely from solution using FFESS by employing a shadow-masking approach. The resultant device performance shows promise towards eventual use in power conversion for large-scale internet of things applications. Because this processing does not rely on vacuum processing and uses relatively few precursor materials, the diode can be cost-effective. Further, the full processing, starting from the substrate, can be performed in less than two hours, allowing for mass production of the diode and circuitry.

The subject-matter of the disclosure may also relate, among others, to the following aspects:

A first aspect relates to a solution-phase processed vertical Schottky diode comprising: a stack of films on a substrate, the stack of films comprising: a first electrode film comprising a noble metal; a first semiconducting film on the first electrode film, the first semiconducting film comprising zinc oxide doped with an electron donor metal at a first dopant concentration; a second semiconducting film on the first semiconducting film, the second semiconducting film comprising zinc oxide doped with the electron donor metal at a second dopant concentration higher than the first dopant concentration; and a second electrode film on the second semiconducting film, the second electrode film comprising a noble metal.

A second aspect relates to the solution-phase processed vertical Schottky diode of the first aspect, wherein the noble metal of the second electrode film is the same as the noble metal of the first electrode film.

A third aspect relates to the solution-phase processed vertical Schottky diode of the first or second aspect, wherein the noble metal is selected from the group consisting of silver, gold, and platinum.

A fourth aspect relates to the solution-phase processed vertical Schottky diode of the third aspect, wherein the noble metal is silver.

A fifth aspect relates to the solution-phase processed vertical Schottky diode of any preceding aspect, wherein the electron donor metal is selected from the group consisting of aluminum, indium, and gallium.

A sixth aspect relates to the solution-phase processed vertical Schottky diode of the fifth aspect, wherein the electron donor metal is aluminum.

A seventh aspect relates to the solution-phase processed vertical Schottky diode of any preceding aspect, wherein the first dopant concentration is selected to form a Schottky contact with the first electrode film.

An eighth aspect relates to the solution-phase processed vertical Schottky diode of any preceding aspect, wherein the second dopant concentration is selected to form a tunneling contact with the second electrode film

A ninth aspect relates to the solution-phase processed vertical Schottky diode of any preceding aspect, wherein the first dopant concentration is less than 1 at. %, and wherein the second dopant concentration is higher than 1 at. %.

A tenth aspect relates to the solution-phase processed vertical Schottky diode of the ninth aspect, wherein the first dopant concentration is in a range from about 0 at. % to about 0.3 at. %, and wherein the second dopant concentration is in a range from about 2 at. % to about 4 at. %.

An eleventh aspect relates to the solution-phase processed vertical Schottky diode of any preceding aspect, wherein the films in the stack are polycrystalline and/or nanocrystalline.

A twelfth aspect relates to the solution-phase processed vertical Schottky diode of the preceding aspect, wherein crystallites in each of the films exhibit a size variation within +/−10% of an average crystallite size.

A thirteenth aspect relates to the solution-phase processed vertical Schottky diode of any preceding aspect, wherein an areal size of some or all of the films in the stack decreases in a direction away from the substrate.

A fourteenth aspect relates to the solution-phase processed vertical Schottky diode of any preceding aspect, wherein a thickness of some or all of the films in the stack increases in a direction away from the substrate.

A fifteenth aspect relates to the solution-phase processed vertical Schottky diode of any preceding aspect, wherein each of the films in the stack has a thickness of 1 micron or less, 500 nm or less, and/or 100 nm or less.

A sixteenth aspect relates to the solution-phase processed vertical Schottky diode of any preceding aspect, wherein a thickness of the first and second semiconductor films defines a distance d between the first and second electrode films, and wherein the distance d is about 450 nm or less.

A seventeenth aspect relates to the solution-phase processed vertical Schottky diode of any preceding aspect, wherein the substrate comprises glass.

An eighteenth aspect relates to the solution-phase processed vertical Schottky diode of any preceding aspect, wherein the substrate comprises a polymer.

A nineteenth aspect relates to the solution-phase processed vertical Schottky diode of any preceding aspect, wherein the noble metal of the second electrode film is the same as the noble metal of the first electrode film, wherein the noble metal comprises silver, wherein the electron donor metal comprises aluminum, wherein the first dopant concentration is selected to form a Schottky contact with the first electrode film, wherein the second dopant concentration is selected to form a tunneling contact with the second electrode film.

A twentieth aspect relates to a solution-phase method of producing a vertical Schottky diode, the method comprising: generating a spray of charged droplets, each charged droplet comprising a metal precursor; collecting the charged droplets on a heated substrate, the metal precursor decomposing and/or reacting to form a film comprising a metal species; repeating the generating and the collecting successively with selected metal precursors to form a stack of the films on the substrate; and selecting the metal precursors such that the stack comprises: a first electrode film; a first semiconducting film on the first electrode film; a second semiconducting film on the first semiconducting film; and a second electrode film on the second semiconducting film, thereby forming a vertical Schottky diode.

A twenty-first aspect relates to the solution-phase method of the twentieth aspect, wherein the first and second electrode films comprise a noble metal, wherein the first and second semiconducting films comprise zinc oxide doped with an electron donor metal, and wherein the metal precursors comprise a first metal precursor and a fourth metal precursor comprising the noble metal; and second metal precursors and third metal precursors comprising zinc and the electron donor metal, respectively.

A twenty-second aspect relates to the solution-phase method of the twenty-first aspect, wherein the noble metal is selected from the group consisting of: silver, gold, and platinum.

A twenty-third aspect relates to the solution-phase method of the twenty-first or twenty-second aspect, wherein the first and fourth metal precursors comprising the noble metal are selected from the group consisting of: silver(I) 2-[2-(2 methoxyethoxy)ethoxy]acetate, silver 2-ethylhexnoate, silver pivalate, silver 2-(2 methoxyethoxy)acetate, and silver oxalate.

A twenty-fourth aspect relates to the solution-phase method of any of the twenty-first through the twenty-third aspects, wherein the electron donor metal is selected from the group consisting of: aluminum, indium, or gallium.

A twenty-fifth aspect relates to the solution-phase method of any of the twenty-first through the twenty-fourth aspects, wherein the second metal precursors comprising zinc are selected from the group consisting of: zinc acetate, zinc nitrate, a zinc carboxylate such as zinc propionate, zinc butanoate, zinc pentanoate, zinc 2-ethylhexanoate, zinc methoxyacetate, zinc methoxyethoxyacetate, and zinc methoxyethoxyethoxyate, and/or wherein the third metal precursors comprising the electron donor metal are selected from the group consisting of: aluminum acetylacetonate, aluminum nitrate, aluminum isopropoxide, aluminum tri-sec-butoxide, aluminum alkyl 3-oxobutanoate, such as ethyl 3-oxobutanoate and butyl 3-oxobutanoate, aluminum tri-n-butoxide, and aluminum ethyl hexanoate.

A twenty-sixth aspect relates to the solution-phase method of any of the twentieth through the twenty-fifth aspects, wherein the first semiconducting film is doped with an electron donor metal at a first dopant concentration, and wherein the second semiconducting film is doped with the electron donor metal at a second dopant concentration higher than the first dopant concentration.

A twenty-seventh aspect relates to the solution-phase method of any of the twentieth through the twenty-sixth aspects, wherein the heated substrate has a temperature greater than 30° C. and less than 300° C.

A twenty-eighth aspect relates to the solution-phase method of the twenty-seventh aspect, wherein the temperature is 290° C. or less, or 200° C. or less, and/or at least 100° C.

A twenty-ninth aspect relates to the solution-phase method of any of the twentieth through the twenty-eighth aspects, being carried out in air at atmospheric pressure.

A thirtieth aspect relates to the solution-phase method of any one of the twentieth through the twenty-ninth aspects, wherein generating the spray of charged droplets comprises field injecting charge into a solution comprising the metal precursor and a solvent.

A thirty-first aspect relates to the solution-phase method of the preceding aspect, wherein field injecting charge into the solution comprises: flowing the solution through a nozzle containing an inner electrode; and applying a charging voltage to the inner electrode.

A thirty-second aspect relates to the solution-phase method of the preceding aspect, wherein the charging voltage is in a range from about 10 kV to about 40 kV, or from about 15 kV to about 25 kV.

A thirty-third aspect relates to the solution-phase method of the thirty-first or thirty-second aspect, wherein a flow rate of the solution through the nozzle is in range from about 5 μl/min to about 50 μl/min, or from about 10 μl/min to about 30 μl/min.

A thirty-fourth aspect relates to the solution-phase method of any of the twentieth through the thirty-third aspects, further comprising positioning a shadow mask on or above the heated substrate to block a portion of the charged droplets, thereby controlling an areal size and shape of the film that forms.

A thirty-fifth aspect relates to the solution-phase method of the preceding aspect, wherein the shadow mask comprises an electrically insulating mask.

A thirty-sixth aspect relates to the solution-phase method of the thirty-fourth aspect, wherein the shadow mask comprises an electrically conductive mask, and further comprising applying a bias voltage to the electrically conductive mask.

A thirty-seventh aspect relates to the solution-phase method of any of the thirty-fourth through the thirty-sixth aspects, wherein the shadow mask is positioned about 200 μm above the heated substrate.

A thirty-eighth aspect relates to the solution-phase method of any of the twentieth through the thirty-seventh aspects, wherein the stack is produced in 120 minutes or less.

A thirty-ninth aspect relates to the solution-phase method of any one of the twentieth through the thirty-eighth aspects, wherein the heated substrate comprises glass.

A fortieth aspect relates to the solution-phase method of any one of the twentieth through the thirty-eighth aspects, wherein the heated substrate comprises a polymer.

A forty-first aspect relates to the solution-phase method of any one of the twentieth through the fortieth aspects, wherein the charged droplets are 100 nm or less in size.

A forty-second aspect relates to the solution-phase method of any one of the twentieth through the forty-first aspects, comprising the stack of films of any one of the first through the nineteenth aspects.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein.

Furthermore, the advantages described above are not necessarily the only advantages of the invention, and it is not necessarily expected that all of the described advantages will be achieved with every embodiment of the invention.

1. A solution-phase processed vertical Schottky diode comprising:
a stack of films on a substrate, the stack of films comprising:
a first electrode film comprising a noble metal;
a first semiconducting film on the first electrode film, the first semiconducting film comprising zinc oxide doped with an electron donor metal at a first dopant concentration;
a second semiconducting film on the first semiconducting film, the second semiconducting film comprising zinc oxide doped with the electron donor metal at a second dopant concentration higher than the first dopant concentration; and
a second electrode film on the second semiconducting film, the second electrode film comprising a noble metal.

2. The solution-phase processed vertical Schottky diode of claim 1, wherein the noble metal of the second electrode film is the same as the noble metal of the first electrode film.

3. The solution-phase processed vertical Schottky diode of claim 1, wherein the electron donor metal is selected from the group consisting of aluminum, indium, and gallium.

4. The solution-phase processed vertical Schottky diode of claim 1, wherein the first dopant concentration is selected to form a Schottky contact with the first electrode film.

5. The solution-phase processed vertical Schottky diode of claim 1, wherein the second dopant concentration is selected to form a tunneling contact with the second electrode film.

6. The solution-phase processed vertical Schottky diode of claim 1, wherein the first dopant concentration is less than 1 at. %, and
wherein the second dopant concentration is higher than 1 at. %.

7. The solution-phase processed vertical Schottky diode of claim 1, wherein an areal size of some or all of the films in the stack decreases in a direction away from the substrate.

8. The solution-phase processed vertical Schottky diode of claim 1, wherein a thickness of some or all of the films in the stack increases in a direction away from the substrate.

9. The solution-phase processed vertical Schottky diode of claim 1,
wherein the noble metal of the second electrode film is the same as the noble metal of the first electrode film,
wherein the noble metal comprises silver,
wherein the electron donor metal comprises aluminum,
wherein the first dopant concentration is selected to form a Schottky contact with the first electrode film,
wherein the second dopant concentration is selected to form a tunneling contact with the second electrode film.

10. A solution-phase method of producing a vertical Schottky diode, the method comprising:
generating a spray of charged droplets, each charged droplet comprising a metal precursor;
collecting the charged droplets on a heated substrate, the metal precursor decomposing and/or reacting to form a film comprising a metal species;
repeating the generating and the collecting successively with selected metal precursors to form a stack of the films on the substrate; and
selecting the metal precursors such that the stack comprises:
a first electrode film;
a first semiconducting film on the first electrode film;
a second semiconducting film on the first semiconducting film; and
a second electrode film on the second semiconducting film, thereby forming a vertical Schottky diode.

11. The solution-phase method of claim 10, wherein the first and second electrode films comprise a noble metal,
wherein the first and second semiconducting films comprise zinc oxide doped with an electron donor metal, and
wherein the metal precursors comprise:
a first metal precursor and a fourth metal precursor comprising the noble metal; and
second metal precursors and third metal precursors comprising zinc and the electron donor metal, respectively.

12. The solution-phase method of claim 11, wherein the noble metal is selected from the group consisting of: silver, gold, and platinum.

13. The solution-phase method of claim 11, wherein the first and fourth metal precursors comprising the noble metal are selected from the group consisting of: silver(I) 2-[2-(2 methoxyethoxy)ethoxy]acetate, silver 2-ethylhexnoate, silver pivalate, silver 2-(2 methoxyethoxy)acetate, and silver oxalate.

14. The solution-phase method of claim 11, wherein the electron donor metal is selected from the group consisting of: aluminum, indium, or gallium.

15. The solution-phase method of claim 11, wherein the second metal precursors comprising zinc are selected from the group consisting of: zinc acetate, zinc nitrate, a zinc carboxylate such as zinc propionate, zinc butanoate, zinc pentanoate, zinc 2-ethylhexanoate, zinc methoxyacetate, zinc methoxyethoxyacetate, and zinc methoxyethoxyethoxyate, and/or
wherein the third metal precursors comprising the electron donor metal are selected from the group consisting of: aluminum acetylacetonate, aluminum nitrate, aluminum isopropoxide, aluminum tri-sec-butoxide, aluminum alkyl 3-oxobutanoate, such as ethyl 3-oxobutanoate and butyl 3-oxobutanoate, aluminum tri-n-butoxide, and aluminum ethyl hexanoate.

16. The solution-phase method of claim 10, wherein the heated substrate has a temperature greater than 30° C. and less than 300° C.

17. The solution-phase method of claim 10, being carried out in air at atmospheric pressure.

18. The solution-phase method of claim 10, wherein generating the spray of charged droplets comprises field injecting charge into a solution comprising the metal precursor and a solvent.

19. The solution-phase method of claim 10, further comprising positioning a shadow mask on or above the heated substrate to block a portion of the charged droplets, thereby controlling an areal size and shape of the film that forms.

20. The solution-phase method of claim 10, wherein the stack is produced in 120 minutes or less.
